(19) United States
(12) Patent Application Publication
(10) Pub. No.: US 2022/0238329 A1
(43) Pub. Date: Jul. 28, 2022

(54) SEMICONDUCTOR LITHOGRAPHY APPARATUS

(71) Applicant: CHANGXIN MEMORY TECHNOLOGIES, INC., Hefei City (CN)

(72) Inventor: Xianyong YU, Hefei (CN)

(73) Assignee: CHANGXIN MEMORY TECHNOLOGIES, INC., Hefei City, Anhui Province (CN)

(21) Appl. No.: 17/494,964

(22) Filed: Oct. 6, 2021

Related U.S. Application Data
(63) Continuation of application No. PCT/CN2021/100906, filed on Jun. 18, 2021.

(30) Foreign Application Priority Data
Jan. 28, 2021 (CN) 202110118289.7

(51) Int. Cl. H01L 21/027; H01L 21/687; H01L 21/67

(52) U.S. Cl. CPC H01L 21/0274; H01L 21/67051; H01L 21/68707

(57) ABSTRACT

The present application provides a semiconductor lithography apparatus, including: a photomask conveying device and a photomask clamping device connected to the photomask conveying device, wherein the photomask clamping device is configured to carry a photomask; and a photomask-cleaning gas jet device connected to the photomask clamping device for jetting a gas to an upper side of the photomask so as to prevent particulate matters from falling on a surface of the photomask.

### CROSS-REFERENCE TO RELATED APPLICATIONS

This application is a continuation application of International Patent Application No. PCT/CN2021/100906 filed on Jun. 18, 2021, which claims priority to Chinese Patent Application No. 202110118289.7, filed on Jan. 28, 2021. The above-referenced patent applications are incorporated herein by reference in their entirety.

### TECHNICAL FIELD

The present application relates to the field of semiconductor technologies, and in particular, relates to a semiconductor lithography apparatus.

### BACKGROUND

A photomask is a template for manufacturing a circuit of a chip. Once the photomask is contaminated, products will be greatly affected. A semiconductor device has a machine station in which a device for detecting particle contamination of the photomask is disposed. The particle contamination of the photomask occurs at an extremely high frequency, which seriously affects the efficiency of the machine station of the semiconductor device. Meanwhile, the machine station checks the particle contamination on a surface of the photomask only regularly instead of all the time, or check it after an exposure process, which results in a problem that a whole batch of products often needs to be reprocessed. If the particle contamination cannot be detected due to a design defect of a detection device per se, product scrap will be caused, which will have a very serious impact on a yield and a cost.

For a semiconductor lithography apparatus in the related art, a photomask conveying process in the semiconductor lithography apparatus will involve a plurality of parts and a large number of mechanical transmission components. In this way, some contaminating particles will be generated during the conveying process and fall on the surface of the photomask to cause contamination. In the related art, the surface of the photomask is cleaned by introducing a cleaning gas towards the surface of the photomask from an upper side of the photomask in the semiconductor lithography apparatus and by blowing the cleaning gas to the surface of the photomask from the top down. However, if the cleaning gas is not clean or a gas introducing pipeline is worn, or if particles are produced due to the inner wear of the semiconductor device in a few days, the particles will, on the contrary, be blown by the cleaning gas from the top down to fall on the surface of the photomask, leading to low efficiency in treating the photomask contamination.

### SUMMARY

The present application provides a semiconductor lithography apparatus.

The semiconductor lithography apparatus according to an embodiment of the present application includes: a photomask conveying device and a photomask clamping device connected to the photomask conveying device, wherein the photomask clamping device is configured to carry a photomask; and a photomask-cleaning gas jet device connected to the photomask clamping device for jetting a gas to an upper side of the photomask so as to prevent particulate matters from falling on a surface of the photomask.

### BRIEF DESCRIPTION OF DRAWINGS

FIG. 1 is a schematic diagram of a connecting structure between a photomask-cleaning gas jet device and a photomask clamping device in a semiconductor lithography apparatus according to an embodiment of the present application;

FIG. 2 is a schematic top view of a connecting structure between the photomask-cleaning gas jet device and the photomask clamping device in the semiconductor lithography apparatus according to an embodiment of the present application;

FIG. 3 is a top view of a photomask-cleaning gas jet device of the semiconductor lithography apparatus according to an embodiment of the present application; and

FIG. 4 is a side view of a photomask-cleaning gas jet device of the semiconductor lithography apparatus according to an embodiment of the present application.

### DESCRIPTION OF EMBODIMENTS

A semiconductor lithography apparatus according to embodiments of the present application will be described below with reference to the accompanying drawings. The semiconductor lithography apparatus when in use may convey and utilize a photomask 200. For example, the semiconductor lithography apparatus according to the embodiments of the present application may be an exposure machine or a lithography machine, which can avoid particle contamination of the photomask 200 during the process of conveying or utilizing the photomask 200, so as to increase an application efficiency of the photomask 200, improve a product yield and reduce a cost.

The semiconductor lithography apparatus according to the embodiments of the present application may include a photomask conveying device, a photomask clamping device, and a photomask-cleaning gas jet device 100.

The photomask conveying device is configured to convey the photomask 200. For example, the photomask conveying device may include a robotic arm, by which the photomask 200 may be conveyed to different parts. The photomask clamping device is connected with the photomask conveying device for clamping and carrying the photomask 200. For example, the photomask clamping device may be connected to an end of the photomask conveying device, the latter is moved to drive the photomask clamping device to move, such that the photomask 200 may be transferred among different positions.

The photomask-cleaning gas-jet device 100 is connected to the photomask clamping device. When carrying the photomask 200 by the photomask clamping device, the photomask-cleaning gas-jet device 100 may be configured to blow a gas towards an upper side of the photomask 200, to prevent contamination caused by particulate matters falling on a surface of the photomask 200. Specifically, during the use of the semiconductor lithography apparatus, for example, during the process of conveying the photomask 200, internal transmission components of the semiconductor lithography apparatus wear out and produce particulate matters. The photomask-cleaning gas-jet device 100 may be configured to jet the gas from the bottom up, not only to prevent the particulate matters from being blown downward to the surface of the photomask 200, but also to blow the falling particulate matters upward to prevent them from falling on the surface of the photomask. Moreover, when a cleaning gas contains contaminating particulate matters or the jetted gas passes through a pipe having particulate matters inside, the particulate matters may also be prevented from falling on the surface of the photomask 200, since the cleaning gas is jetted upward.

As a result, by providing the photomask-cleaning gas jet device 100 in the semiconductor lithography apparatus according to the embodiments of the present application, the photomask-cleaning gas jet device 100 may jet the gas from the bottom up to prevent the particulate matters from falling on the surface of the photomask 200, thereby reducing the contamination of the photomask 200, increasing the utilization rate of the photomask 200, and further improving the product yield and reducing the cost.

For a gas jet direction of the photomask-cleaning gas jet device 100, the photomask-cleaning gas jet device 100 may jet a gas upward inclinedly towards the photomask 200, which may not only prevent the particulate matters from falling on the surface of the photomask 200, but also allow the particulate matters to inclinedly move following the gas by means of inclined gas-jetting and to be jetted out of a corresponding area above the surface of the photomask 200, so as to further prevent the contamination caused by the particulate matters falling on the surface of the photomask 200. Optionally, an inclination angle between the gas jet direction of the photomask-cleaning gas-jet device 100 and the surface of the photomask 200 may range from 25° to 75°, for example, the inclination angle between the gas jet direction of the photomask-cleaning gas-jet device 100 and the surface of the photomask 200 may be 60°.

In some embodiments of the present application, the photomask-cleaning gas jet device 100 may include a gas jet pipe 1 and a nozzle 15 communicated with the gas jet pipe 1, where the gas jet pipe 1 is connected to a gas source of the cleaning gas jetted by the photomask-cleaning gas-jet device, such that delivering the cleaning gas may be accomplished. The nozzle 15 is configured to jet the cleaning gas, that is, the cleaning gas delivered by the gas jet pipe 1 is jetted by the nozzle 15, by which a jet direction of the cleaning gas may be defined.

One end of the nozzle 15 is connected to the gas jet pipe 1, and the other end of the nozzle 15 extends upward inclinedly towards a position where the photomask 200 is disposed, such that the gas jet direction of the nozzle 15 is inclined upward with respect to the surface of the photomask 200. In other words, the nozzle 15 are disposed inclinedly with respect to the surface of the photomask 200 and extend upward. In this way, the cleaning gas may be jetted upward inclinedly by the nozzle 15 to form a cleaning area above the photomask 200 for preventing the particulate matters from falling on the photomask 200.

Optionally, as shown in FIG. 4, an inclination angle a between the gas-jet direction of the nozzle 15 and the surface of the photomask 200 ranges from 25° to 75°. For example, the inclination angle a between the gas jet direction of the nozzle 15 and the surface of the photomask 200 may be 30°, 40°, or 50°. As a result, the particulate matters may be not only blown upward and prevented from falling on the surface of the photomask 200, but also blown out of the corresponding area above the photomask 200. Preferably, the inclination angle a between the gas jet direction of the nozzle 15 and the surface of the photomask 200 is 60°.

In an example shown in FIG. 4, when the nozzle 15 is disposed inclinedly and the photomask 200 is carried on the photomask clamping device, an included angle between the nozzle 15 and a plane, in which the photomask 200 is disposed, ranges from 25° to 75°. That is, the inclination angle of the nozzle 15 with respect to the surface of the photomask 200 ranges from 25° to 75°, and preferably the inclination angle of the nozzle 15 with respect to the surface of the photomask 200 is 60°.

In some examples of the present application, the photomask-cleaning gas-jet device 100 may jet the gas to at least two opposite sides of the photomask 200, such that the cleaning gas may form a convective area above the photomask 200 since the cleaning gas on each side of the photomask 200 is jetted upward inclinedly with respect to the surface of the photomask 200. As a result, the flow mildness of the cleaning gases may be improved, and the particulate matters may be further prevented from falling on the surface of the photomask 200.

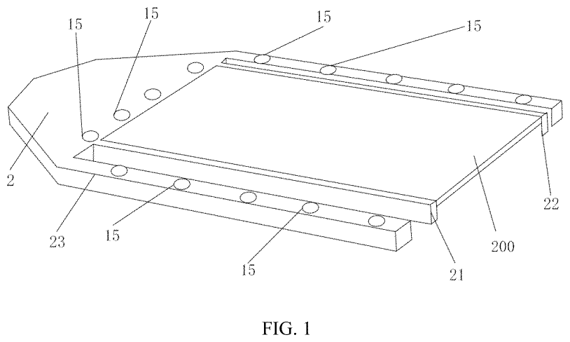

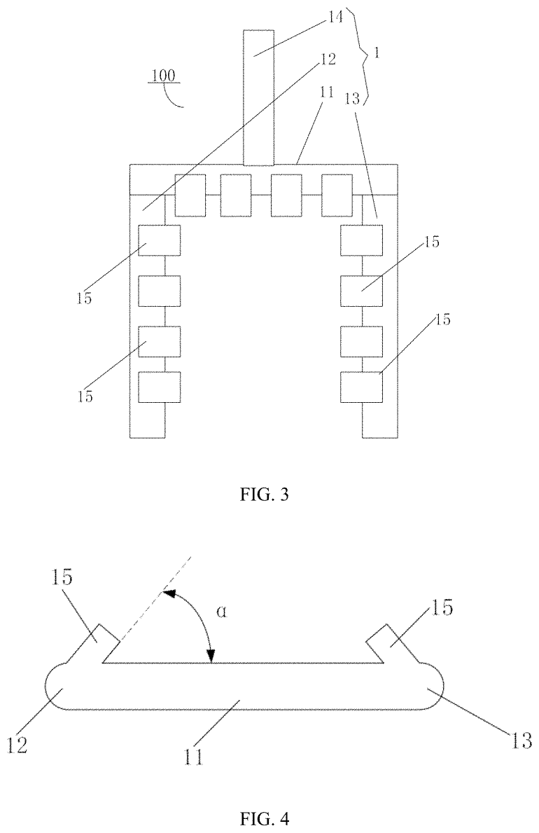

Specifically, at least two opposite sides of the photomask 200 may be provided with the nozzles 15 to form the convective gas jet area above the photomask 200. In other words, the nozzles 15 may be disposed outside the photomask 200. That is, the nozzles 15 may be disposed on an outer side of an outer edge of the photomask 200, and extend upward inclinedly towards a position where the photomask 200 is disposed, so as to produce the cleaning gas inclining upward. Moreover, the nozzles 15 may be formed at least on both sides of the photomask 200. For example, as shown in FIGS. 1 to 4, the nozzles 15 may be formed on left and right sides of the photomask 200 and at the same time on a front side of the photomask 200, such that when the nozzles 15 jet the gas, a convective gas jet area may be formed above the photomask 200 to further prevent the particulate matters from falling on and contaminating the photomask 200.

In some specific examples of the present application, the gas jet pipe 1 may include a first pipe 11, a second pipe 12, and a third pipe 13. Ends of the first pipe 11 are connected with one end of the second pipe 12 and one end of the third pipe 13 on the same side, respectively. The second pipe 12 and the third pipe 13 are disposed on two opposite sides of the photomask 200 respectively; the first pipe 11, the second pipe 12, and the third pipe 13 surround the photomask 200; and the first pipe 11, the second pipe 12 and the third pipe 13 are all provided with the nozzles 15.

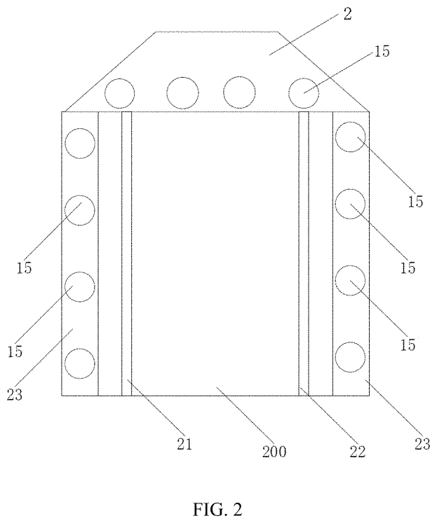

As shown in FIGS. 2 and 4, the second pipe 12, the first pipe 11, and the third pipe 13 are connected in sequence to partially surround the photomask 200. Specifically, the first pipe 11 and the third pipe 13 are arranged in parallel and disposed outside two opposite sides of the photomask 200; ends of the first pipe 11 are connected to the second pipe 12 and the third pipe 13, respectively; and the nozzles 15 are formed on the first pipe 11, the second pipe 12, and the third pipe 13, such that cleaning gases may be jetted on at least two opposite sides of the photomask 200, thereby forming the convective gas-jet area above the photomask 200.

For the shape of the nozzle 15, the nozzle 15 may be flat, and may extend along an extension direction of the gas jet pipe 1. For example, the first pipe 11 may be provided with a first nozzle 15, and the second pipe 12 may be provided with a second nozzle 15; and the third pipe 13 may be further provided with a third nozzle 15. Moreover, one first nozzle 15 is provided and has a flat shape extending along a length direction of the first pipe 11; one second nozzle 15 may be provided and formed in a flat shape extending along a length direction of the second pipe 12; and one third nozzle 15 may be provided and formed in a flat shape extending along a length direction of the third pipe 13.

Alternatively, the nozzle 15 may be formed in a hollow cylindrical structure, and a plurality of nozzles 15 may be provided and disposed at even intervals along the extension direction of the gas jet pipe 1. In this way, the intensity of a gas flow jetted by the nozzles 15 may be enhanced, thereby blowing off the particulate matters. As shown in FIG. 1, a plurality of the nozzles 15 are provided and are disposed on the first pipe 11, the second pipe 12 and the third pipe 13 at even intervals.

Optionally, both the second pipe 12 and the third pipe 13 are in communication with the first pipe 11, and the gas jet pipe 1 further includes a fourth pipe 14, which is in communication with the first pipe 11 and a gas source. As a result, the gas source may deliver the cleaning gas to the first pipe 11 through the fourth pipe 14, and the cleaning gas flows to the second pipe 12 and the third pipe 13 respectively through the first pipe 11, thereby facilitating the delivery of the cleaning gas and enabling the cleaning gas to be jetted out through the nozzles 15 on the first pipe 11, the second pipe 12 and the third pipe 13.

Further, the photomask conveying device includes a robotic conveying arm, in which the fourth pipe 14 is disposed. Specifically, the gas source may be disposed in a machine station of the semiconductor lithography apparatus; and the fourth pipe 14 is penetratively disposed in the robotic conveying arm to facilitate the connection between the fourth pipe 14 and the gas source. When the robotic conveying arm moves to transfer the photomask 200, the fourth pipe 14 may move with the robotic conveying arm. As a result, during the process of moving the photomask 200, the photomask-cleaning air-jet device 100 may also clean the photomask 200 to prevent the particulate matters from falling on the surface of the photomask 200. Moreover, the fourth pipe 14 may also be protected by the robotic conveying arm.

In some embodiments of the present application, the photomask-cleaning gas jet device 100 further includes at least one control valve. The control valve is disposed on the gas jet pipe 1 for controlling on-off of the gas jet pipe 1. As a result, the gas jetting of the nozzles 15 on the gas jet pipe 1 may be controlled by the control valve, so as to prevent the particulate matters from falling by jetting the gas when the photomask 200 is disposed on the photomask clamping device. The control valve may be provided as one or more in number. When a plurality of control valves are provided, the control valves may be disposed on different positions of the gas jet pipe 1. In this way, the gas-jet pipe 1 may be divided into a plurality of sections, and the plurality of control valves control on/off of the plurality of sections of the gas jet pipe 1, respectively, so as to control, by the control valves, different sections of the gas-jet pipe 1 to jet the gas. As a result, the different nozzles 15 of the gas jet pipe 1 may be controlled to jet the gas according to cleaning needs.

Optionally, three control valves may be provided and are disposed on the first pipe 11, the second pipe 12 and the third pipe 13 respectively, so as to control the photomask-cleaning gas jet device 100 to jet the gas to different sides of the photomask 200. Specifically, by the three control valves, the on/off of the first pipe 11, the second pipe 12 and the third pipe 13 may be separately controlled to further control the gas jetting of the nozzles 15 on the first pipe 11, the second pipe 12 and the third pipe 13. By turning on and off different control valves, the nozzles 15 on the first pipe 11, the second pipe 12, and the third pipe 13 jet the gas or do not jet the gas. In this way, each control valve may be adjusted according to actual cleaning needs, such that the cleaning gas is jetted to different sides of the photomask 200 through the nozzles 15 to further prevent the contamination caused by the particulate matters.

In some embodiments of the present application, the photomask clamping device includes a clamping plate 2 for carrying and clamping the photomask 200; the clamping plate 2 is provided with a through hole penetrating in a thickness direction thereof; the photomask-cleaning gas jet device 100 is connected below the photomask clamping device; and the nozzle 15 is penetratively disposed in the through hole, which facilitates the connection of the photomask-cleaning gas jet device 100 with the photomask clamping device. As shown in FIG. 1, the photomask 200 is carried on a substantially middle position of the clamping plate 2; and a plurality of through holes are provided and are disposed on an area that surrounds and supports the photomask 200. The photomask-cleaning gas-jet device 100 is provided with a plurality of nozzles 15, which are disposed in a one-to-one correspondence with the plurality of through holes; and each of the nozzles 15 is correspondingly installed in the corresponding through hole such that the plurality of nozzles 15 may be disposed around the photomask 200. The through holes penetrate through the clamping plate 2 along the thickness direction of the clamping plate 2, the photomask-cleaning gas jet device 100 is disposed below the clamping plate 2, and the nozzles 15 pass through the through holes so as to be exposed from a surface of the clamping plate 2, thereby jetting the cleaning gas upward inclinedly towards a position where the photomask 200 is disposed.

Optionally, an upper surface of the nozzle 15 is flush with an upper surface of the clamping plate 2. In this way, when the photomask 200 is carried on the clamping plate 2, the upper surface of the nozzle 15 may be flush with the surface of the photomask 200, such that the leaning gas may be jetted inclinedly towards the upper side of the photomask 200 when the nozzle 15 jet the gas.

Further, the clamping plate 2 is provided with a groove on the bottom thereof; the gas-jet pipe 1 is embedded in the groove; and the nozzle 15 is disposed in the through hole. As a result, by embedding the gas jet pipe 1 in the groove, the clamping plate 2 and the photomask-cleaning gas-jet device 100 may be fixedly connected to prevent the nozzle 15 from falling out of the through hole. Moreover, this structure is simple and the connection is convenient.

As shown in FIG. 1, the clamping plate 2 includes a first clamping and carrying portion 21 and a second clamping and carrying portion 22, which are disposed oppositely at an interval, for fixing the photomask 200. Specifically, the first clamping and carrying portion 21 and the second clamping and carrying portion 22 are disposed in parallel at an interval. The photomask 200 is carried between the first clamping and carrying portion 21 and the second clamping and carrying portion 22. The clamping plate 2 further includes photomask-cleaning carrying portions 23, which are configured to connect the photomask-cleaning gas jet device 100. The photomask-cleaning carrying portions are disposed on outer sides of the first clamping and carrying portion and the second clamping and carrying portion, and the photomask-cleaning gas jet device 100 is connected to the photomask-cleaning carrying portions 23, such that the photomask-cleaning gas-jet device 100 may be disposed around the photomask 200 to jet the gas upward inclinedly towards the photomask 200.

Described above are merely preferred embodiments of the present application. It should be noted that for those of ordinary skills in the art, a number of improvements and modifications can be made without departing from the principle of the present application, and shall be construed as falling within the protection scope of the present application.

What is claimed is:

1. A semiconductor lithography apparatus, comprising:
a photomask conveying device and a photomask clamping device connected to the photomask conveying device, wherein the photomask clamping device is configured to carry a photomask; and
a photomask-cleaning gas jet device connected to the photomask clamping device for jetting a gas to an upper side of the photomask so as to prevent particulate matters from falling on a surface of the photomask.

2. The semiconductor lithography apparatus according to claim 1, wherein the photomask-cleaning gas-jet device comprises a gas-jet pipe and a nozzle communicated with the gas jet pipe; one end of the nozzle is connected with the gas jet pipe, and the other end of the nozzle extends upward inclinedly towards a position where the photomask is disposed, such that a gas jet direction of the nozzle is inclined upward with respect to the surface of the photomask.

3. The semiconductor lithography apparatus according to claim 2, wherein an inclination angle between the gas jet direction of the nozzle and the surface of the photomask ranges from 25° to 75°.

4. The semiconductor lithography apparatus according to claim 3, wherein the inclination angle between the gas jet direction of the nozzle and the surface of the photomask is 60°.

5. The semiconductor lithography apparatus according to claim 2, wherein at least two opposite sides of the photomask are provided with the nozzles so as to form a convective gas-jet area above the photomask.

6. The semiconductor lithography apparatus according to claim 5, wherein the gas jet pipe comprises a first pipe, a second pipe, and a third pipe; ends of the first pipe are connected to one end of the second pipe and one end of the third pipe on the same side, respectively; the second pipe and the third pipe are disposed on two opposite sides of the photomask, respectively; and the first pipe, the second pipe and the third pipe surround the photomask and are all provided with the nozzles.

7. The semiconductor lithography apparatus according to claim 6, wherein a plurality of the nozzles are provided, and are disposed on the gas jet pipe at even intervals.

8. The semiconductor lithography apparatus according to claim 6, wherein the second pipe and the third pipe are both in communication with the first pipe, and the gas-jet pipe further comprises a fourth pipe, which is in communication with the first pipe and a gas source.

9. The semiconductor lithography apparatus according to claim 8, wherein the photomask conveying device comprises a robotic conveying arm, and the fourth pipe is disposed within the robotic conveying arm.

10. The semiconductor lithography apparatus according to claim 6, wherein the photomask-cleaning gas jet device further comprises at least one control valve, which is disposed on the gas jet pipe for controlling on/off of the gas jet pipe.

11. The semiconductor lithography apparatus according to claim 10, wherein three control valves are provided, and are disposed on the first pipe, the second pipe and the third pipe respectively to control the photomask-cleaning gas jet device to jet the gas to different sides of the photomask.

12. The semiconductor lithography apparatus according to claim 2, wherein the photomask clamping device comprises a clamping plate for carrying and clamping the photomask; the clamping plate is provided with a through hole penetrating in a thickness direction thereof; and the photomask-cleaning gas jet device is connected below the photomask clamping device and the nozzle is penetratively disposed in the through hole.

13. The semiconductor lithography apparatus according to claim 12, wherein an upper surface of the nozzle is flush with an upper surface of the clamping plate.

14. The semiconductor lithography apparatus according to claim 12, wherein the clamping plate is provided with a groove on a bottom thereof; the gas-jet pipe is embedded in the groove; and the nozzle is disposed within the through hole.

15. The semiconductor lithography apparatus according to claim 12, wherein the clamping plate comprises a first clamping and carrying portion and a second clamping and carrying portion, which are disposed oppositely at an interval, for fixing the photomask; and the clamping plate further comprises photomask-cleaning carrying portions, for connecting the photomask-cleaning gas-jet device, disposed on outer sides of the first and second clamping and carrying portions.
